(19) United States
(12) Patent Application Publication
(10) Pub. No.: US 2007/0200109 A1
(43) Pub. Date: Aug. 30, 2007

(54) Method for the manufacture of a piezoelectric component

(76) Inventors: Giacomo Sciortino, Osnabrueck (DE); Christopher A. Goat, Offham (GB)

Correspondence Address: DELPHI TECHNOLOGIES, INC., M/C 480-410-202, PO BOX 5052, TROY, MI, 48007, US

(21) Appl. No.: 11/707,289

(22) Filed: Feb. 16, 2007

(30) Foreign Application Priority Data
Feb. 16, 2006 (EP) 06003197.8

(51) Int. Cl. H01L 31/00; H01L 29/06

(52) U.S. Cl. 257/17

(57) ABSTRACT

A method for the determination of the arrangement of electrodes in the manufacture of a piezoelectric component, in particular of a piezoactuator, comprises the steps of making available of a base body consisting of a multilayer structure of at least one piezoelectric ceramic layer and at least two electrodes, wherein the base body has at least two outer surfaces and at least one electrode extends at least regionally up to at least one of the outer surfaces and is exposed at one end there, whereas the at least two electrodes on at least one further outer surface are not exposed, and removal of the material from the outer surface on which the electrodes are not exposed, using an electrically conductive stripper, wherein, on the removal of the material from the one outer surface, an electrical voltage is applied between the stripper, which is adapted so as to facilitate the removal of the material and at least one electrode and the electrical current flowing through the at least one electrode on the removal of the material is measured.

### TECHNICAL FIELD

The present invention relates to a method for the determination of the arrangement of electrodes in the manufacture of a piezoelectric component, in particular of a piezoactuator, to a method of manufacturing a piezoelectric component using the aforesaid method and to a piezoelectric component.

### BACKGROUND OF THE INVENTION

Known piezoactuators typically have a stack of alternating (inner) electrodes and piezoceramic layers, with the individual inner electrodes being surrounded at both sides by a piezoceramic layer in each case and the individual piezoceramic layers—with the exception of those arranged at the margin of the stack —being surrounded at both sides by an inner electrode in each case. In this context, respectively adjacent electrodes separated from one another by a piezoceramic layer have a different polarity so that, when an electrical voltage is applied between two respectively adjacent inner electrodes, an electrical field is formed in each case. This is achieved from a construction aspect, for example, in that a respective end of every second inner electrode is electrically conductively connected to a metal layer functioning as a first outer electrode and applied to a first side surface of the piezoactuator which is of parallelepiped shape as a rule, whereas a respective end of the other electrodes is in contact with a metal layer which is applied to a second side surface of the piezoactuator disposed opposite the first and acts as a second outer electrode.

To avoid a short circuit between the inner electrodes of a first polarity and the outer electrode of opposite polarity on the operation of the component, the individual inner electrodes typically do not extend over the total width of the cross-sectional plane bounded by the side surfaces provided with one respective outer electrode each, but—starting from the side surface having the outer electrode of the same polarity to which the inner electrode is connected—only up to a specific spacing from the oppositely disposed side surface on which the second outer electrode of opposite polarity is arranged. A respective axially extending marginal region is thereby formed at the two side surfaces provided in each case with an outer electrode and only inner electrodes of one polarity are located therein. In these marginal regions, when an electrical voltage is applied between the outer electrodes, no electrical field is consequently generated so that these marginal layers are piezoelectrically inactive.

To restrict these piezoelectrically inactive regions to the axial marginal regions of the two side surfaces with an outer electrode arranged thereon, the individual inner electrodes extend in a throughgoing manner in the transverse direction thereto so that the individual electrodes extend up to the two surfaces of the side surfaces of the piezoactuator having no outer electrode and are exposed there.

Ideally, the piezoelectrically inactive marginal regions have a constant width over their total length. However, the individual steps of the manufacture of a piezoelectric component, namely lamination of the individual layers of the component, pressing of the multilayer structure, cutting to size and sintering of the component, result in a deformation of the multilayer structure so that the ends of the individual electrodes in the piezoelectrically inactive regions do not lie precisely above one another. Due to this deformation, deviations arise in the width of the piezoelectrically inactive regions, with respect to the length of the component, and indeed typically random deviations, systematic linear deviations, systematic curved deviations or a combination of two or more of the aforesaid deviations.

These deviations in the width of the piezoelectrically inactive marginal regions represent a problem because these regions are not poled during the normal poling procedure and are therefore also not subject to any longitudinal poling growth. These poling irregularities cause a compression strain in the poled region as well as a tensile stress in the piezoelectrically inactive region. To the extent that the piezoelectrically inactive regions are not symmetrical along the length of the multilayer structure, these strains can cause a deformation or even a breakage of the component.

To minimize the deviations in the width of the piezoelectrically inactive marginal regions, the precise position of the electrodes within the multilayer structure must be localized in the manufacture of the component and the component must be reworked mechanically, where necessary, such that the variations in the width of the piezoelectrically inactive marginal regions lie within an acceptable range. Previously known methods for the localization of the position of the individual electrodes in a piezoelectric multilayer structure are based on a purely optical detection of the position of the electrodes and are correspondingly imprecise.

### SUMMARY OF THE INVENTION

It is therefore the object of the present invention to provide a method for the determination of the arrangement of electrodes in the manufacture of a piezoelectric component, in particular of a piezoactuator, in which the position of the individual electrodes in the multilayer structure, and in particular the geometry of the piezoelectrically inactive marginal regions, can be determined fast, simply and reliably in order to be able to obtain a component on the basis of the determined position of the individual electrodes by any required reworking of the piezoelectric component in which the piezoelectrically inactive marginal regions have a constant width along the length of the component.

This object is satisfied in accordance with the invention by a method having the features of claim 1 and in particular by a method for the detection of the arrangement of electrodes in the manufacture of a piezoelectric component, in particular of a piezoactuator, comprising the steps:

a) providing a base body made of a multilayer structure consisting of at least one piezoelectric ceramic layer and at least two electrodes, with the base body having at least two outer surfaces and the at least two electrodes extending at least regionally up to at least one of the outer surfaces and being exposed at one end there, whereas the at least two electrodes on at least one further outer surface are not exposed; and

b) removing the material of the at least one outer surface on which the electrodes are not exposed, using a stripper, until at least one of the electrodes is exposed at one end on this outer surface,

wherein the stripper is electrically conductive; on the removal of the material of the at least one outer surface in step b), an electrical voltage is applied between the stripper and at least one of the electrodes; and the electrical current flowing through the at least one electrode is measured on the removal of the material.

Since, on the removal of the material of the at least one outer surface on which the electrodes are not exposed, which is typically piezoelectric ceramic material, an electrical voltage is applied between the electrically conductive stripper, which is adapted for the removal of the material, for example a grinding device, and at least one of the electrodes and since the electrical current flowing through this electrode on the removal of the material is measured, it is possible to determine the time at which this electrode is exposed at the outer surface since, at this time, the stripper, which is adapted so as to facilitate the removal of the material of the at least one outer surface, comes into contact with at least one end of the electrode so that an electrical current flows through the electrode due to the voltage applied between the stripper and the electrode. Provided that the electrical voltage is applied between the stripper and at least two electrodes, it is possible to detect with the method in accordance with the invention the time and the location at which the first of the electrodes provided with electrical voltage is exposed at the corresponding outer surface since in this case this electrode comes into electrical contact with the stripper. Since the surface of a piezoelectric component is divided into individual sectors and the electrodes of each sector are each connected to a different voltage source or to a different channel of a voltage source, it can be determined using the method in accordance with the invention at which time and at which position the respective first electrode of each sector is exposed at the corresponding outer source. With knowledge of the precise position of the electrode first exposed per respective sector, i.e. of the electrode located furthest to the outside in this sector, it is possible to determine the geometry of the piezoelectric marginal regions over the length of the component and, to the extent it differs from the desired ideal shape, to bring it into the desired shape by a corresponding post-treatment of the outer surfaces.

For the removal of the material from the at least one outer surface in accordance with step b) of the method in accordance with the invention, all the techniques familiar to the person skilled in the art can be used with which piezoelectric ceramic material can be removed from a multilayer structure of electrodes and piezoelectric ceramic layers. It has in particular proven to be advantageous within the framework of the present invention to remove the material from the at least one outer surface by grinding using a grinding medium.

The present invention is also not limited with respect to the type of the grinding medium. The grinding medium is preferably a grinding wheel.

To achieve a good electrical connection between the electrically conductive grinding medium and the electrode to be exposed on the outer surface of the base body, it has proven to be advantageous to use a grinding medium for the removal of the material comprising a metal wheel on whose surface abrasive particles are arranged. Such a grinding medium has good electrical conductivity due to the metal wheel which can consist, for example, of nickel or of a nickel chromium alloy. Since, in addition, parts of the surface of the metal wheel between the individual abrasive particles are exposed, the metal wheel supplied with electrical voltage comes into electrical contact with the electrode on the exposure of an electrode at the outer surface of the multilayer structure so that electrical current flows through the electrode and the metal wheel and the exposed electrode can be detected accordingly.

To achieve a sufficient grinding effect and permanence of the grinding medium, it is proposed in a further development of the idea of the invention to provide abrasive particles of diamond and/or boron nitride on the metal wheel of the grinding medium.

The method in accordance with the invention is not limited with respect to the level of the voltage to be applied between the stripper, which is adapted so as to facilitate the removal of the material and the at least one electrode.

The manufacture of the base body can take place in accordance with any method familiar to the skilled person for this purpose. A method comprising the following steps is named merely by way of example:

a₁) stacking of at least one piezoelectric ceramic section and of at least two electrodes to form a multilayer structure in which the individual layers are arranged disposed alternately over one another;

a₂) pressing of the multilayer structure manufactured in step a₁);

a₃) optionally, division of the multilayer structure into a plurality of multilayer structures, for example by cutting the stack into a plurality of small stacks;

a₄) sintering of the multilayer structures generated in step a₂) or in step a₃); and

a₅) removal of the material at least one outer surface of the multilayer structure or structures until at least one electrode extends at least regionally up to the outer surface and is exposed at one end there.

For the stacking in accordance with step a₁), individual piezoelectric ceramic layers and electrode layers can, for example, be placed alternately over one another. Alternatively to this, is it also possible to manufacture a plurality of multilayer structures belonging to different piezoelectric components in parallel in one workstep. The latter can be achieved, for example, in that for the stacking in accordance with step a₁), one or more layers of unfired piezoelectric ceramic material and a layer of unfired piezoelectric ceramic material, on which in each case a plurality of at least substantially square-shaped metal coatings are arranged spaced apart from one another, are placed alternately over one another. In this connection, the metal coatings disposed in each case over one another and separated from one another by one or more layers of unfired piezoelectric ceramic material later form the inner electrodes of a piezoelectric component, whereas adjacent metal coatings on the same cross-sectional plane are separated to form different components. This can be achieved, for example, in that the laminate in the intermediate regions is cut in the axial direction between the individual metal coatings.

To form the later piezoelectrically inactive marginal regions of a desired geometry, it is proposed in a further development of the idea of the invention to place the individual layers over one another in step a₁) such that the individual electrodes each separated from one another by one or more piezoelectric ceramic layers are mutually laterally offset in the transverse direction. The piezoelectrically inactive marginal regions are thus obtained by grinding the corresponding outer surfaces in step b) of the method in accordance with the invention. The electrodes are preferably disposed in alignment over one another in the other transverse direction.

In accordance with a further preferred embodiment of the present invention, in step a₅), material is removed at the at least one outer surface until all the electrodes extend at least regionally up to the outer surface and are exposed there. It is thereby ensured that all the electrodes can be connected to a voltage source or, divided into sectors, to different voltage sources in order, in the carrying out of step b) of the method in accordance with the invention, to be able to determine the position of the electrode exposed first or of the electrode exposed first within a sector.

To expose the electrodes on the at least one outer surface in step a₅) of the method in accordance with the invention, the corresponding outer surface can be ground for so long using a grinding medium, for example a grinding wheel, until the ends of individual electrodes or of all electrodes on the outer surface are exposed. The grinding can take place, on the one hand, with the jacket surface of the grinding wheel or, on the other hand, with the circular base surface of the grinding wheel. The last-named embodiment has the advantage that, due to the larger area of the base surface in comparison with the jacket surface of the grinding wheel, a plurality of multilayer structures can be ground simultaneously so that it is possible to work under milder grinding conditions, i.e. under lower thermal and mechanical strain for the multilayer structures, with the same throughput.

It has furthermore proven to be advantageous within the framework of the present invention to make the base body made available in step a) substantially in parallelepiped shape, with the at least one piezoelectric layer and the at least two electrodes being arranged at least substantially horizontally in the base body and the electrodes extending from a side surface of the base body to a side surface of the base body disposed opposite thereto and in each case being exposed at one end on each of the two side surfaces.

In accordance with a further preferred embodiment of the present invention, in step b) of the method, the material is removed at two oppositely disposed side surfaces of the multilayer structure until an end of at least one electrode is exposed in each case on each of the two side surfaces. In this manner, a piezoelectric component is obtained which has a respective piezoelectrically inactive marginal region at two oppositely disposed side surfaces.

The manner of the application of the electrical voltage between the stripper and at least one of the electrodes depends on which information should be obtained using the method in accordance with the present invention. To the extent it is only a small electrical component with few electrode layers, it is has e.g. provided to be sufficient on the application of the electrical voltage between the stripper and at least one of the electrodes to attach an outer electrode to at least one outer surface of the base body on which at least one electrode is exposed and to connect it to a voltage source. All the electrodes exposed on the at least one outer surface of the base body are thereby connected to the voltage source via the outer electrode such that, on the removal of the material of the at least one outer surface on which the electrodes are initially not exposed, a significant electrical current flows through the outer electrode as soon as the first inner electrode connected thereto is exposed on the outer surface and as a consequence comes into contact with the stripper, for example a grinding medium. If the precise position of the grinding medium at this time is known, a conclusion can be drawn on the precise position of the end of the corresponding electrode from the starting of the electrical current flow. Since the same procedure is repeated on the outer surface disposed opposite the outer surface, the precise position of the first electrode exposed on the other outer surface is also determined so that a conclusion can be drawn on the geometry and any incorrect arrangement of the piezoelectrically inactive marginal regions from the two measured points.

To the extent larger piezoelectric components are used or a higher resolution of the geometry of the piezoelectrically inactive marginal regions in a piezoelectric component should be reached, it has proved to be advantageous for the application of the electrical voltage between the stripper and at least one of the electrodes on at least one outer surface of the base body on which at least one electrode is exposed to attach a plurality of mutually separate outer electrodes and to connect each of the outer electrodes with its own voltage source. The outer surface to be ground is thereby basically divided into individual sectors, with the respective electrodes on the corresponding outer surface exposed inside this sector being connected to one of the outer electrodes. It is possible by this arrangement not only to detect the position of the first exposed electrode on the total outer surface, but also the position of each of the respectively first exposed electrodes in the individual sectors. Relatively precise conclusions can thus be drawn on the geometry of the piezoelectrically inactive marginal regions.

To increase the resolution of the method in accordance with the invention even further, it is proposed in a further development of the idea of the invention, for the application of the electrical voltage between the stripper and at least one of the electrodes on two mutually oppositely disposed side surfaces of the base body on which in each case at least one electrode is exposed, to attach a respective plurality of mutually separate outer electrodes and to connect each of the outer electrodes to a voltage source. The precise position of the respective electrodes first exposed per sector on each of the two side surfaces is thus obtained so that there are sufficient measured points to be able to draw a conclusion back to the precise geometry of the piezoelectrically inactive marginal regions.

Each of the aforesaid embodiments, in particular the last-named embodiment, can be realized particularly simply when the at least one outer electrode is an electrically conductive clamp since this can be simply fastened to the two oppositely disposed side surfaces of the base body.

A further subject of the present invention is a method for the manufacture of a piezoelectric component, in particular of a piezoactuator, comprising the aforesaid steps in which, after the determination of the arrangement of the electrodes in the piezoelectric component, for the optimization of the electrode, in particular for the achievement of a desired geometry of the piezoelectrically inactive marginal regions, one or more of the outer surfaces of the piezoelectric component is reground on the basis of the measured values obtained.

Piezoelectric components which can be obtained using the method in accordance with the invention are in particular characterized by a geometry of the piezoelectrically inactive marginal regions corresponding to the demands so that strains and deformations of the component due to defective positions inside the piezoelectrically inactive marginal regions can be avoided.

### BRIEF DESCRIPTION OF THE DRAWINGS

The present invention will be described in the following purely by way of example with reference to advantageous embodiments and to the enclosed drawings. There are shown:

FIG. 1 is a perspective view of a base body made available in step a) of the method in accordance with the invention with electrical connections;

FIG. 2 is schematically, the method step b) of the method in accordance with the invention; and

FIG. 3 is the arrangement of the piezoelectrically inactive marginal regions of a piezoelectric component determined using the method in accordance with the invention.

### DESCRIPTION OF THE PREFERRED EMBODIMENT

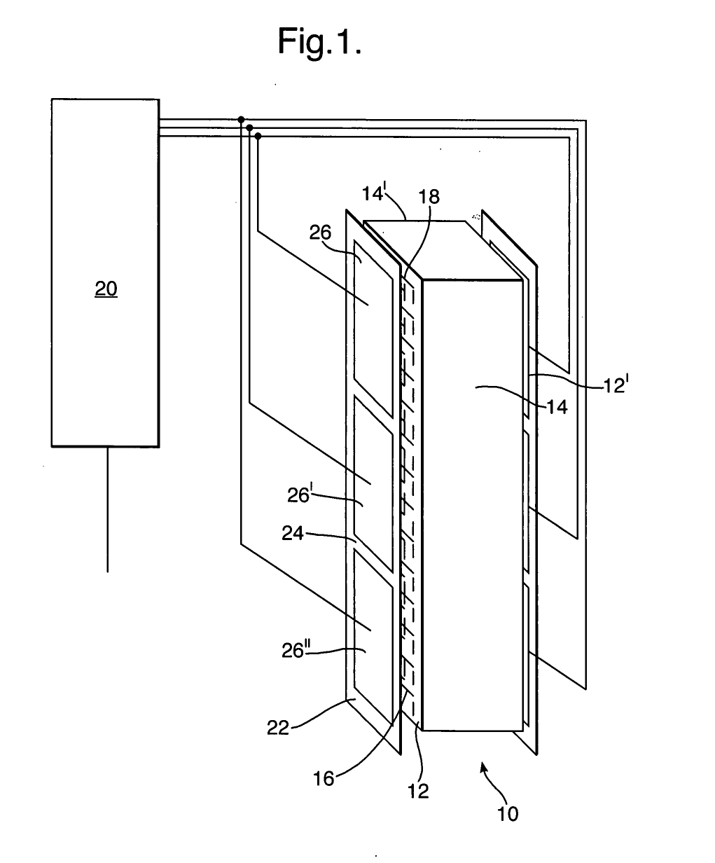

The base body 10 shown schematically in FIG. 1 is made in parallelepiped form and comprises four side surfaces 12, 12′, 14, 14′, a base surface and a top surface. It consists of alternately arranged layers of piezoelectric ceramic material 16 and electrodes 18, with the individual layers 16, 18 being arranged disposed over one another in the form of a stack and—with the exception of the topmost and bottommost layers—a respective piezoelectric ceramic layer 16 being surrounded by two electrodes 18 and each electrode 18 being surrounded by two respective piezoelectric ceramic layers 16.

All the electrodes 18 extend in a throughgoing manner from the cross-sectional plane defined by the side surfaces 12, 12′, with a respective end of the electrodes 18 being exposed on the two side surfaces 12, 12′.

As can be recognized on the side surface 12 in FIG. 1, the individual electrodes 18 are not disposed in alignment over one another in the cross-sectional plane defined by the side surfaces 14, 14′, but are laterally offset so that axial marginal regions are formed at the two longitudinal sides of the base body 10 in FIG. 1, said marginal regions being shown in broken lines and with only every second electrode 18 extending through them. These marginal regions are not poled in the poling so that they are piezoelectrically inactive in the later piezoelectric component. In addition, piezoelectric ceramic material 16 is located between the individual ends of the electrodes and the side surfaces 14, 14′ and must be removed to expose the electrode ends offset in each case laterally at the corresponding side surface 14, 14′ on the corresponding side surfaces 14, 14′, that is to expose the ends of the first, third, fifth, etc. electrode on the side surface 14 and to expose the ends of the second, fourth, sixth, etc. electrode on the side surface 14′.

Before the individual ends of the electrodes 18 are exposed on the side surfaces 14, 14′, the individual electrodes of the base body 10 are applied to a voltage source 20. For this purpose, respective clamps 22 are applied to the two side surfaces 12, 12′ and are each divided into electrically conductive sectors 26, 26′, 26″ separated from one another by electrically insulating material 24. Each sector 26, 26′, 26″ is respectively connected to a different channel of the voltage source 20. In addition, the voltage source is connected at its other pole to a grinding wheel (not shown in FIG. 1) to apply an electrical voltage between the grinding wheel and the individual sectors 26, 26′, 26″ or the electrodes 18 in contact therewith.

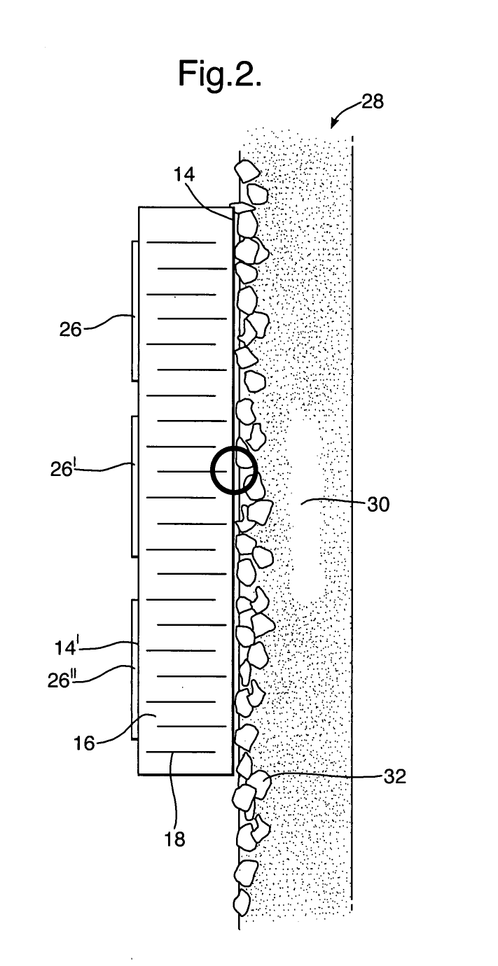

To expose the individual ends of the electrodes 18 on the side surfaces 14, 14′, the side surface 14 is first ground using a grinding wheel 28, as shown in FIG. 2. The grinding wheel 28 comprises a metal wheel 30 made of a nickel chromium alloy on whose grinding surface abrasive particles 32 of boron nitride are arranged.

During the grinding, the surface to be ground is sprayed with a water-based coolant to avoid overheating of the material to be ground. This coolant has low electrical conductivity so that a low electrical current is already flowing between the grinding wheel 28 and the individual electrodes 18 exposed on the side surfaces, 12, 12′ even if the electrically conductive metal wheel 30 still does not contact any electrode 18 on the side surface 14. This low current flow increases in the degree in which the metal wheel 30 spatially approaches the electrodes 18. At that moment where the metal wheel 30 exposes an end of an electrode 18 on the side surface 14 with its abrasive particles 32 arranged thereon, the metal wheel 30 is only separated from the electrode 18 marked by the circle in FIG. 1 and exposed on the side surface 14 by the height of the abrasive particles 32, i.e. by fractions of a micrometer, so that a dramatic increase in the current flow through the corresponding electrode 18 occurs due to the voltage applied between the metal wheel 30 and the electrodes 18. Since this current flow is limited to the electrodes 18 of that sector 26′ which are connected to the same channel of the voltage source 20, the increase in the current flow can be associated with the exposure of the first end of an electrode 18 from the corresponding sector 26′. In contrast, no current flow can be found in the two other channels of the voltage source 20 at this point in time. On a further progressing of the grinding process, finally the ends of the first electrodes of the other two sectors 26, 26″ are also finally successively exposed, after which a dramatic increase in the current flow can also be recorded in the corresponding channels of the voltage source 20 which are associated with these sectors 26, 26″. At the end of the grinding process, the positions of the ends of the respective electrodes 18 first exposed per sector 26, 26′, 26″ are thus known.

The same grinding process is now also repeated on the side surface 14′ disposed opposite the side surface 14, whereby the position of the electrode ends 18 first exposed per sector 26, 26′, 26″ in each case on this side surface 14′ is also known. For this purpose, the base body 10 is not removed from the clamp 22, but the clamp 22 is only rotated to direct the side surface 14′ toward the grinding wheel 28. The relative position of the base body is thereby not changed in the axial direction so that the position of the exposed electrodes 18 in each sector 26, 26′, 26″ remains known.

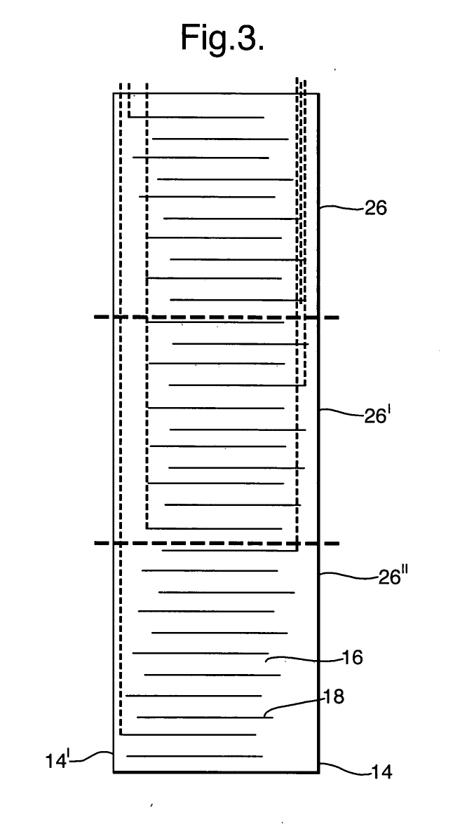

Overall, from the results thus obtained, under the assumption that the lateral defective position of the electrodes along the axial direction of the base body 10 is uniform within correspondingly small sectors, the relative orientation of the individual electrodes 18 with respect to one another results such as is shown by way of example in FIG. 3. In this context, the broken lines in each case show the electrodes 18 first exposed in the individual sectors 26, 26′, 26 of the two side surfaces 14, 14′. For purposes of illustration, only three sectors 26, 26′, 26″ are shown in the Figures and the defective positions within the piezoelectrically inactive marginal regions are shown in an exaggerated manner. In reality, considerably more than three sectors are used per piezoelectric component to obtain a very precise resolution of the position of the individual electrodes in the multilayer structure.

Since the relative position of the individual electrodes with respect to one another and the extent of the piezoelectrically inactive marginal regions are now known, it can be achieved by a corresponding reworking, such as regrinding, of the two side surfaces 14, 14′ that the piezoelectrically inactive marginal regions adopt the required shape.

1. A method for the determination of the arrangement of electrodes in the manufacture of a piezoelectric component, in particular a piezoactuator, comprising the steps of:
a) providing a base body made of a multilayer structure consisting of at least one piezoelectric ceramic layer and at least two electrodes, with the base body having at least two outer surfaces and at least one electrode extending at least regionally up to at least one of the outer surfaces and being exposed at one end there, whereas the at least two electrodes on at least one further outer surface are not exposed; and
b) removing the material of the at least one outer surface on which the electrodes are not exposed using a stripper until at least one of the electrodes is exposed at one end on this outer surface, wherein
the stripper is electrically conductive; on the removal of the material of the at least one outer surface in step b), an electrical voltage is applied between the stripper and at least one of the electrodes; and the electrical current flowing through the at least one electrode is measured on the removal of the material.

2. A method in accordance with claim 1, wherein the removal of the material in step b) takes place by grinding using a grinding medium, preferably a grinding wheel.

3. A method in accordance with claim 2, wherein the grinding medium comprises a metal wheel on whose surface abrasive particles are arranged.

4. A method in accordance with claim 3, wherein the metal wheel consists of nickel or of a nickel chromium alloy and/or the abrasive particles consist of diamond and/or boron nitride.

5. A method in accordance with claim 1, wherein the following steps are carried out for the provision of the base body in accordance with step a):
a₁) stacking of at least one piezoelectric ceramic section and of at least two electrodes to form a multilayer structure in which the individual layers are arranged disposed alternately over one another;
a₂) pressing of the multilayer structure manufactured in step a₁);
a₃) optionally, dividing the multilayer structure into a plurality of multilayer structures;
a₄) sintering of the multilayer structure or structures; and
a₅) removal of the material at at least one outer surface of the multilayer structure or structures until at least one electrode extends at least regionally up to the at least one outer surface and is exposed at one end there.

6. A method in accordance with claim 5, wherein, for the stacking in accordance with step a₁), one or more layers of unfired piezoelectric ceramic material and a layer of unfired piezoelectric ceramic material, on which in each case a plurality of at least substantially square-shaped metal coatings are arranged, preferably by printing, spaced apart from one another, placed over one another.

7. A method in accordance with claim 5, wherein the individual layers are placed over one another in step a₁) such that the individual electrodes respectively separated from one another by one or more piezoelectric ceramic layers are offset laterally with respect to one another in a transverse direction, whereas the electrodes preferably lie in alignment over one another in the other transverse direction.

8. A method in accordance with claim 5, wherein, in step a₅), material is removed at at least one outer surface for so long until all the electrodes extend at least regionally up to the outer surface and are exposed there at one end.

9. A method in accordance with claim 1, wherein the base body made available in step a) is substantially made in parallelepiped shape, with the at least one piezoelectric ceramic layer and the at least two electrodes being arranged at least substantially horizontally in the base body and the electrodes extending from one side surface of the base body to an oppositely disposed side surface of the base body and respectively being exposed at one end on each of the two side surfaces.

10. A method in accordance with claim 1, wherein, in step b), the material is removed at two mutually oppositely disposed side surfaces of the multilayer structure until in each case at least one end of at least one electrode is exposed on each of the two side surfaces.

11. A method in accordance with claim 1, wherein, for the application of the electrical voltage between the stripper and at least one of the electrodes on at least one outer surface of the base body on which at least one electrode is exposed, a plurality of mutually separate outer electrodes are applied and each of the outer electrodes is connected to its own voltage source.

12. A method in accordance with claim 11, wherein, for the application of the electrical voltage between the stripper and at least one of the electrodes on two mutually oppositely disposed side surfaces of the base body (10) on which in each case at least one electrode is exposed, in each case a plurality of mutually separate outer electrodes are applied and each of the outer electrodes is connected to a voltage source.

13. A method for the manufacture of a piezoelectric component, in particular of a piezoactuator, comprising a method in accordance with any one of the claims 1 to 12 and, optionally, final regrinding of at least one outer surface to optimize the electrode arrangement.

14. A piezoelectric component, in particular a piezoactuator, obtainable by a method in accordance with claim 13.DP-314607
